(19) United States
(12) Patent Application Publication
(10) Pub. No.: US 2026/0255507 A1
(43) Pub. Date: Aug. 27, 2026

(54) TAMPER DETECTION SYSTEM FOR DETECTION OF UNAUTHORIZED ACCESS TO A CIRCUIT BOARD

(71) Applicant: Schneider Electric Systems, USA, Inc., Foxborough, MA (US)

(72) Inventors: Yuanbing Li, Foxborough, MA (US); James Pagella, Foxborough, MA (US); Stephen Neave, Foxborough, MA (US)

(73) Assignee: Schneider Electric Systems, USA, Inc., Foxborough, MA (US)

(21) Appl. No.: 19/062,815

(22) Filed: Feb. 25, 2025

(51) Int. Cl. H05K 5/02

(52) U.S. Cl. CPC H05K 5/0208

(57) ABSTRACT

A method and system of detecting unauthorized access to a circuit board is provided. The method includes causing unbiasing of a biasing component in response to a position of the circuit board being changed relative to a housing within which the circuit board is disposed. A burst of kinetic energy that was included in mechanical energy stored by the biasing component is released in response to the unbiasing of the biasing component. A spike of electrical charge is released in response to the burst of kinetic energy. Performance of a protective action to a protected element is caused in response to the spike of electrical charge.

### FIELD

This disclosure relates generally to security of electrical devices, and more particularly, to tamper detection of unauthorized access to a circuit board.

### BACKGROUND

Industrial devices may store security-related information that should only be accessible to authorized users. A tamper detection system can be used to detect an unauthorized attempt to gain access to the security-related information. For example, the tamper detection system can cause erasure of security information from a circuit that was tampered with and setting of a flag in a memory of the circuit.

The tamper detection system may use batteries or supercapacitors to supply power to the protected circuit for erasing the information and/or setting the flag. While a battery can typically provide enough power to the tamper detection system for years, a supercapacitor (that can perform the same function as the battery) only provides power for several weeks. In both cases, the lifetime of the battery and the supercapacitor can be less than a lifetime of the industrial device (or other electrical device) being protected. Replacement of an expired battery or supercapacitor can be a time consuming task. Some industrial sites have hundreds or thousands of electrical devices, each of which may have a tamper detection system that needs to be maintained. Additionally, such industrial devices can be in a remote location or can be difficult to access (e.g., a sensor in a bore of an oil production site).

Additionally, a battery in a tamper detection system can be subjected to shipment requirements and limitations, which can be imputed to the electrical devices the tamper detection system is protecting.

### SUMMARY

The purpose and advantages of the below described illustrated embodiments will be set forth in and apparent from the description that follows. Additional advantages of the illustrated embodiments will be realized and attained by the devices, systems and methods particularly pointed out in the written description and claims hereof, as well as from the appended drawings. To achieve these and other advantages and in accordance with the purpose of the illustrated embodiments, in one aspect, disclosed is a tamper detection system for detection of unauthorized access to a circuit board. The tamper detection system includes a housing within which the circuit board is disposed and a mechanical energy component coupled to the circuit board and configured to move between a biased position to a release position when tampering causes a position of the circuit board to be changed relative to the housing. When in the biased position, a biasing component of the mechanical energy component is biased and stores mechanical energy, and in response to moving to the release position, the biasing component becomes unbiased and releases a burst of kinetic energy. The tamper detection system further includes an electrical energy component configured to release a spike of electrical charge in response to the burst of kinetic energy and a protection circuit configured to respond to the spike of electrical charge by causing performance of a protective action to a protected element.

In one or more embodiments, when the mechanical energy component is disposed in the biased position, the housing, due to a shape of the housing, can cause the biasing component to be biased, and when the mechanical energy component is disposed in the release position, the housing, due to the shape of the housing, can cause the biasing component to be unbiased.

In one or more embodiments, the mechanical energy component can be further configured to move from an initial position to the bias position when tampering causes the position of the circuit board to be changed relative to the housing, wherein when in the initial position, the biasing component can be caused by the housing, due to the a shape of the housing, to be less biased than when in the bias position, and moving from the initial position to the bias position can cause the biasing component to generate and store at least a portion of the mechanical energy.

In one or more embodiments, the energy component can include a piezoelectric member formed of a piezoelectric material, and the kinetic energy can cause mechanical deformation of the piezoelectric material, which can cause the piezoelectric material to release the spike of electrical charge.

In one or more embodiments, wherein the energy component can include a magnet and a coil formed of wire having one or more turns, wherein the kinetic energy can cause relative movement between the magnet and the coil to induce a current, wherein the induced current can cause release of the spike of electrical charge.

In one or more embodiments, the protective action can include causing erasure of stored security-related information, disabling one or more functions provided by one or more circuits, outputting an alarm indication, record a security breach event, and/or reporting the security breach event.

In one or more embodiments, the protection action can be performed immediately after the spike of electrical charge is released or following a delay after the spike of electrical charge is released.

In one or more embodiments, the protective action can be performed in response to powerup or an action of a device that includes or is coupled to the circuit board and/or the protected element.

In one or more embodiments, the industrial device can operate in an operational technology portion of an industrial system.

In one or more embodiments, the shape of the housing can include a notch having a first level and a second level different than the first level. When the mechanical energy component is disposed in the bias position relative to the housing, the first level of the notch can cause the housing to apply a first force to a force applicator of the mechanical energy component, and the force applicator can apply a biasing force to the biasing component, which can cause the biasing to be biased. When the mechanical energy component is disposed in the release position relative to the housing, the second level of the notch can cause the housing to apply less of the force to the force applicator, and the force applicator can apply less or no biasing force to the biasing component, which can cause the biasing to be unbiased.

In accordance with another aspect of the disclosure, a method of detecting unauthorized access to a circuit board is disclosed. The method includes causing, in response to a position of the circuit board being changed relative to a housing within which the circuit board is disposed, unbiasing of a biasing component, releasing, in response to the unbiasing of the biasing component, a burst of kinetic energy included in mechanical energy stored by the biasing component, releasing, in response to the burst of kinetic energy, a spike of electrical charge, and causing, in response to the spike of electrical charge, performance of a protective action to a protected element.

In one or more embodiments, releasing the spike of charge can be caused by mechanical deformation of a piezoelectric material of a piezoelectric member, the mechanical deformation being in response to the release of the kinetic energy.

In one or more embodiments, releasing the spike of charge can be caused by induction of a current caused by relative movement between a magnet and a coil formed of wire having one or more turns, the relative movement being in response to the release of the kinetic energy.

In one or more embodiments, the protective action can include causing erasure of stored security-related information, disabling one or more functions provided by one or more circuits included in or coupled to the circuit board, outputting an alarm indication, record a security breach event, and/or reporting the security breach event.

In one or more embodiments, the protection action can be performed immediately after the spike of electrical charge is released or following a delay after the spike of electrical charge is released.

In one or more embodiments, the protective action can be performed in response to powerup or an action of a device that includes or is coupled to the circuit board and/or the protected element.

In one or more embodiments, the method can further include causing the biasing component to be biased and store at least a portion of the mechanical energy in response to the housing, due to a shape of the housing, causing application by the housing of a first force to the biasing component, wherein when the position of the circuit board is changed relative to the housing, the housing can cause application of no force or a second force that is less than the first force to the biasing component. In one or more embodiments, causing the application by the housing of the first force to the biasing component can be in response to an initial change in the position of the circuit board relative to the housing that precedes the position of the circuit board being changed relative to the housing.

In accordance with still a further aspect of the disclosure, an industrial device is provided. The industrial device includes a circuit board, a housing within which the circuit board is disposed, and a mechanical energy component coupled to the circuit board and configured to move between a biased position to a release position when tampering causes a position of the circuit board to be changed relative to the housing. When in the biased position, a biasing component of the mechanical energy component is biased and stores mechanical energy. The biasing component becomes unbiased and releases a burst of kinetic energy in response to moving to the release position. The industrial device further includes an electrical energy component coupled to the mechanical energy component and configured to release a spike of electrical charge in response to the burst of kinetic energy, a protection circuit in operable communication with the circuit board and configured to respond to the spike of electrical charge by causing performance of a protective action to protect a protected element that is in operable communication with the protection circuit.

In one or more embodiments, when the mechanical energy component is disposed in the biased position, the housing, due to a shape of the housing, can cause the biasing component to be biased, and when the mechanical energy component is disposed in the release position, the housing, due to its shape, can cause the biasing component to be unbiased.

These and other features of the systems and methods of the subject disclosure will become more readily apparent to those skilled in the art from the following detailed description of the preferred embodiments taken in conjunction with the drawings.

### BRIEF DESCRIPTION OF THE DRAWINGS

A more detailed description of the disclosure, briefly summarized above, may be had by reference to various embodiments, some of which are illustrated in the appended drawings. While the appended drawings illustrate select embodiments of this disclosure, these drawings are not to be considered limiting of its scope, for the disclosure may admit to other equally effective embodiments.

FIG. 1A is a schematic diagram of a first embodiment of a tamper detection system deployed on a printed circuit board and in a first state prior to or at an early stage of a tampering operation, in accordance with embodiments of the disclosure;

FIG. 1B is a schematic diagram of the tamper detection system in the first embodiment and in a second state as the tempering operation proceeds, in accordance with embodiments of the disclosure;

FIG. 1C is a schematic diagram of the tamper detection system in the first embodiment and in a third state as the tempering operation proceeds further, in accordance with embodiments of the disclosure;

FIG. 2A is a schematic diagram of a second embodiment of a tamper detection system deployed on a printed circuit board and in a first state prior to or at an early stage of a tampering operation, in accordance with embodiments of the disclosure;

FIG. 2B 1C is a schematic diagram of the tamper detection system in the second embodiment and in a second state as the tempering operation proceeds, in accordance with embodiments of the disclosure; and

FIG. 3 is a flowchart of an example method detecting unauthorized access to a circuit board, in accordance with embodiments of the disclosure.

Identical reference numerals have been used, where possible, to designate identical elements that are common to the figures. However, elements disclosed in one embodiment may be beneficially utilized on other embodiments without specific recitation.

### DETAILED DESCRIPTION

The present disclosure is directed to a self-energized tamper detection system that can be used with a circuit board for preventing unauthorized access to the circuit board. The circuit board can be integrated in an industrial device and may store security-related information. In the event of an attempted unauthorized access, the tamper detection system utilizes a combination of electrical and mechanical energy components to provide a spike of energy to the circuit board and/or the industrial device that causes erasure of the security-related information before it is accessed.

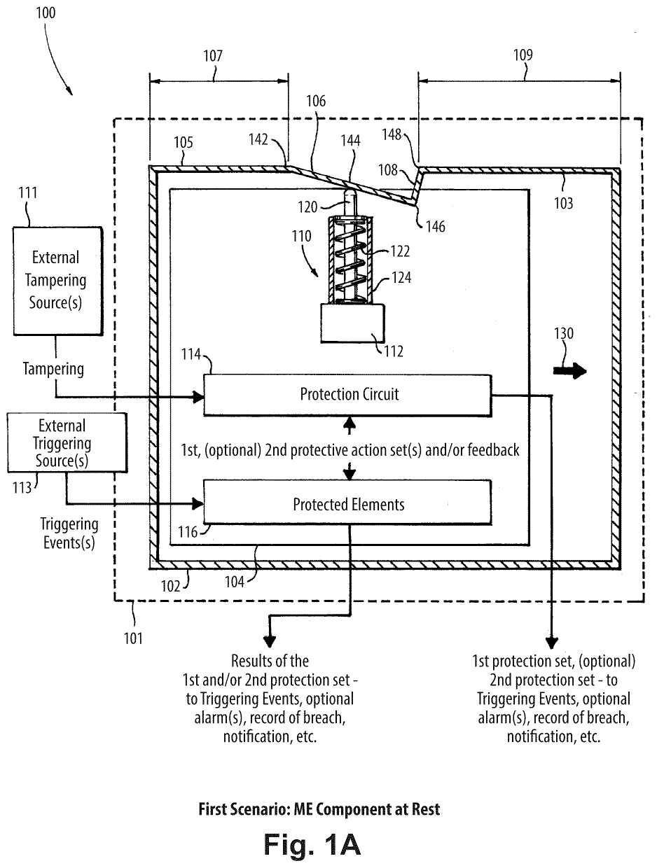

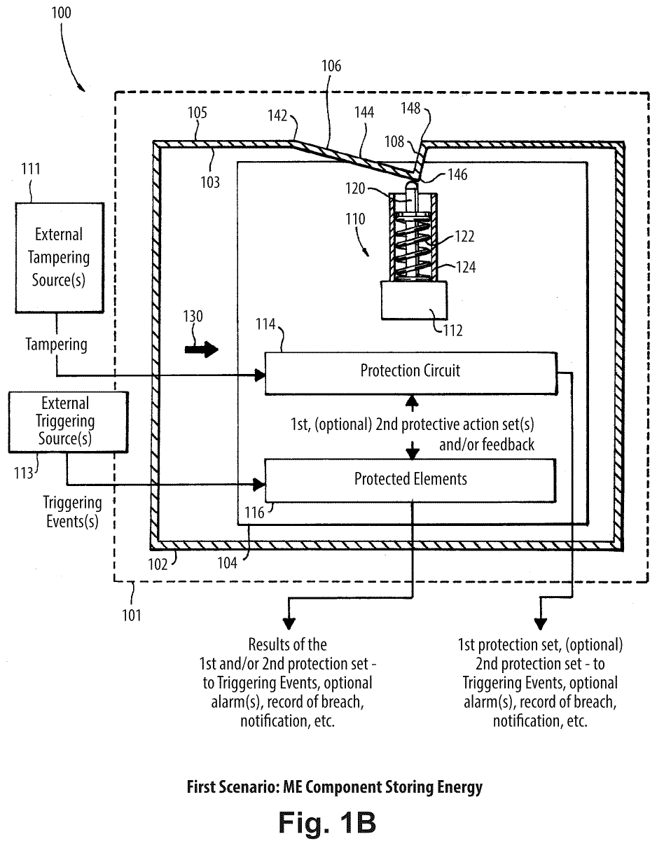

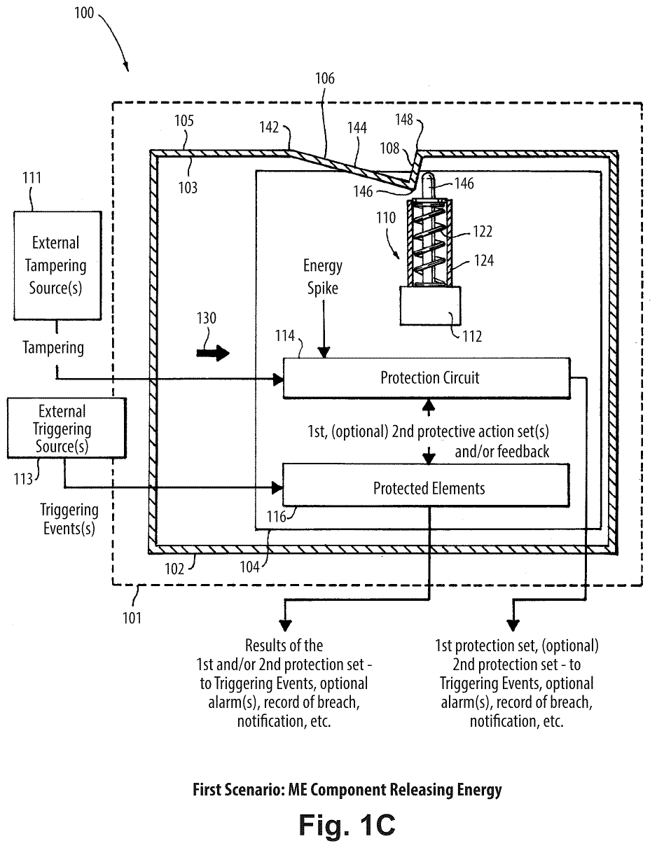

Reference will now be made to the drawings wherein like reference numerals identify similar structural features or aspects of the subject disclosure. For purposes of explanation and illustration, and not limitation, a block diagram of an exemplary embodiment of a tamper detection system in accordance with the disclosure is shown in FIG. 1A and is designated generally by reference character 100. Other embodiments of the tamper detection system 100 in accordance with the disclosure, or aspects thereof, are provided in FIGS. 1B-3, as will be described.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, exemplary methods and materials are now described.

It must be noted that as used herein and in the appended claims, the singular forms “a,” “an,” and “the” include plural referents unless the context clearly dictates otherwise. Thus, for example, reference to “a stimulus” includes a plurality of such stimuli and reference to “the signal” includes reference to one or more signals and equivalents thereof known to those skilled in the art, and so forth.

It is to be appreciated aspects of the embodiments of this disclosure as discussed below can be implemented using a software algorithm, program, or code that can reside on a computer useable medium for enabling execution on a machine having a computer processor. The machine can include memory storage configured to provide output from execution of the computer algorithm or program.

As used herein, the term “software” is meant to be synonymous with any logic, code, or program that can be executed by a processor of a host computer, regardless of whether the implementation is in hardware, firmware or as a software computer product available on a memory storage device or for download from a remote machine. The embodiments described herein include such software to implement the equations, relationships, and algorithms described above. One skilled in the art will appreciate further features and advantages of the disclosure based on the above-described embodiments. Accordingly, the disclosure is not to be limited by what has been particularly shown and described, except as indicated by the appended claims.

In instances where examples are provided, the examples are not intended to be limiting or limited to the particular examples provided.

FIG. 1A is a schematic diagram showing a tamper detection system mounted on a printed circuit board (PCB) 104 of an industrial device 101 and includes at least a portion of a protective housing 102 that houses PCB 104, a mechanical energy (ME) component 110, an electrical energy (EE) component 112, and a protection circuit 114.

Tamper detection system 100 is configured to detect an occurrence of physical tampering with PCB 104 (e.g., by an external tampering source 111), and in at least some embodiments, the detection capability is available for a lifetime of PCB 104 and is further not subjected to shipment restrictions. At least some embodiments include a tamper detection system 100 that is configured to operate without the need for a supercapacitor or a power supply.

Protective housing 102 and ME component 110 are configured to interact with each other so that when either of protective housing 102 and PCB 104 are moved relative to one another (such as due to an unauthorized attempted removal of either housing 102 or PCB 104) the ME component 110 will cause a spurt of mechanical energy. The spurt of mechanical energy causes EE component 112 to release a spike of electrical energy. The spike of electrical energy causes protection circuit 114 and/or protected elements 116 to perform at least one protective action.

The at least one protective action can include a first protective action set and can optionally include a second protective action set. An action set can include one or more actions. At least a portion of the first protective action set can occur immediately in response to the spike of energy.

Alternatively or additionally, in one or more embodiments, at least a portion of the second protective action set can be configured to be contingent on the performance of at least a portion of the first protective action set, as represented by the bidirectional arrow between protection circuit 114 and protected element(s) 116. The direction from protected element(s) 116 to protection circuit 114 represents feedback from protected element(s) about performance of the at least a portion of the first protective action set. In one or more embodiments, at least a portion of the second protective action set can be triggered to occur at a future time (e.g., when a user powers on industrial device 101 or a different device coupled (e.g., electronically and/or mechanically) to protection circuit 114 and/or PCB 104) responsive to a triggering event.

The triggering event can be caused by components included in industrial device 101 (e.g., protection circuit 114 and/or protected element(s) 116) or by one or more external tampering sources 113. The external triggering source(s) 113 can include, for example, a device that is operably coupled (e.g., electronically and/or mechanically) to industrial device 101. Examples of couplings between external triggering source(s) 113 and industrial device 101 include couplings that are wired, wireless, direct, and/or via a network (which can include a cloud). Examples of such actions that could lead to triggering events, in at least some embodiments, include power up of industrial device 101 or external triggering device(s) 142, attempted or successful digital access (for communication with or control of the industrial device 101) by external triggering device(s) 142, attempted or successful digital access to a particular function or component of the industrial device 101 by external triggering device(s) 142, etc. For example, attempted or successful digital access to a particular function or component of the industrial device 101 can include attempted or successful digital access by (for communication with or control of) external triggering device(s) 142.

In one or more embodiments, the first protective action set can erase sensitive data included in protected elements 116, preventing access to the sensitive data.

In one or more embodiments, the first protective action set can set a flag included in protected elements 116. In one or more embodiments, the flag provides an indicator to a user that uses industrial device 101 at a future time that tampering with the industrial device 101 was detected.

In one or more embodiments, the flag can trigger future actions included in second protective action set, such as erasure of sensitive data included in protected elements 116 and/or disabling of components included in or controlled by protected elements 116.

Industrial device 101, in at least some embodiments, is a computing device that includes one or more processing components (e.g., a CPU, microprocessor, field programmable gate array (FPGA), application specific integrated circuit (ASIC), etc.). Industrial device 101 can be configured as, for example, an end device of an operational technology (OT) portion of an industrial system, such as an actuator, sensor, or alarm; an edge device of the industrial system coupled between the OT portion and an information technology (IT) portion of the industrial system, such as a device configured to communicate with multiple end devices, to aggregate data from the multiple end devices, to provide control to the end device(s), and/or to leverage larger processing resources of the IT portion (e.g., an enterprise system); a server of a distributed or centralized control system included in the OT portion; a server of a distributed or centralized control system in the IT portion; a device included in the IT portion (a server, desktop computer, mobile device, etc.). In one or more embodiments, industrial device 101 can be a device that is not industrial or used in an industrial environment.

PCB 104 is disposed in industrial device 101 and includes circuitry mounted on a circuit board, wherein the circuitry and/or PCB 104 can include any of the one or more processing components and/or peripherals of the processing component(s). The circuitry mounted on PCB 104 can include protection circuit 114 and/or protected elements 116. PCB 104 can also be embodied as a circuit board that is not printed (e.g., a bread board, perfboard, stripboard, or wire-wrap board, without limitation). Regardless of whether protection circuit 114 and protected elements 116 are mounted on PCB 104, protection circuit 114 and protected elements 116 are communicatively coupled to one another, e.g., via one or more electrical conductors or other energy paths. Protection circuit 114 can send signals to protection circuit via the communication coupling to cause the protective action(s).

Protective housing 102 is configured to house PCB 104 and can be made of a hard or flexible material (e.g., plastic, metal, rubber). Protective housing 102 houses PCB 104 by holding it in an installed position. Protective housing 102 is configured to physically interact with ME component 110 so that physical removal of PCB 104 from protective housing 102 (or removal of protective housing 102 from PCB 104) will cause a release of a burst of mechanical energy by ME component 110. Protective housing 102 can be an outermost housing of industrial device 101 or can be housed by an outermost housing of industrial device 101.

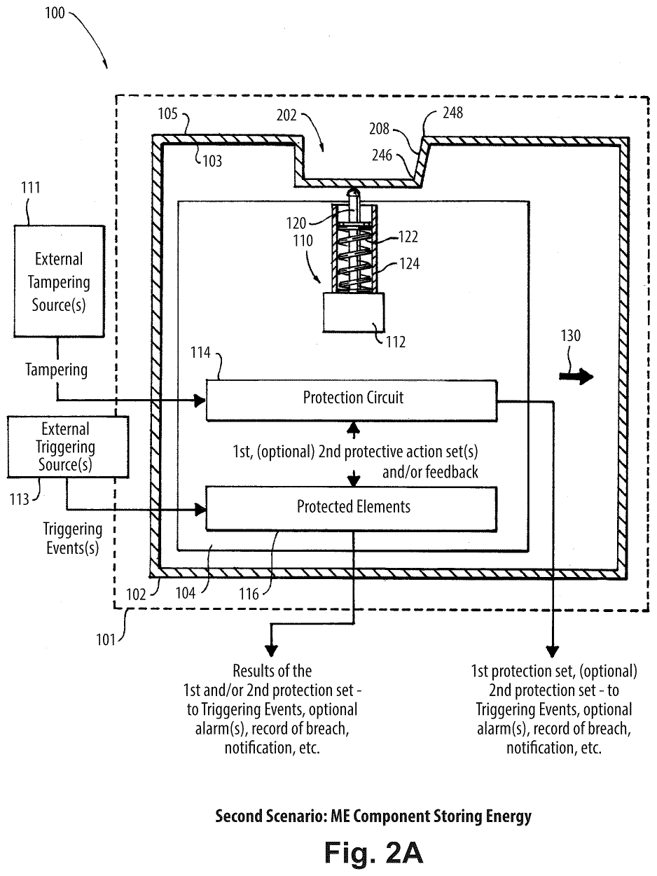

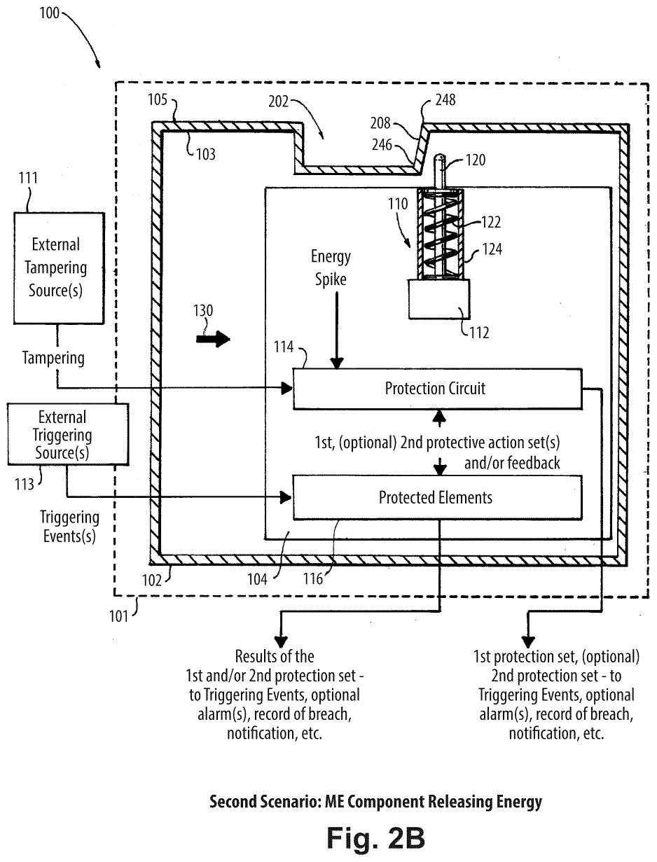

Protective housing 102 is further configured to interact with ME component 110 to cause ME component 110 to store mechanical energy when in an untampered state, and to release a burst of kinetic energy when tampering occurs. ME component 110 can contact inner surface 103 of a particular side 105 of protective housing 102. Side 105 is depicted in FIGS. 1A-2B as a top side, but is not limited to a particular side and can be any side of housing 102. This contact between inner surface 103 can cause application of a compressive force to ME component 110. Protective housing 102 can be shaped to apply a different amount of compressive force or no compressive force to ME component ME 110, depending on which part of inner surface 103 is contacted by force applicator 120.

ME component 110 includes a biasing component 122 that causes ME component 110 to be disposed in a biased position when a biasing force is applied. When the biasing force is removed (fully or partially), biasing component 122 causes ME component 110 to be disposed in an unbiased position (in which all or some of the bias has been removed). Moving from the biased position to the unbiased position causes a release of mechanical energy. When removal of the biasing force is sudden and ME component 110 moves suddenly from the biased position to the unbiased position, a spurt of mechanical energy is released.

In the examples shown in FIGS. 1A-2B, mechanical energy component 110 includes at least one biasing component 122 and at least one corresponding force applicator 120. Biasing component 122 is shown as a compressive element that can be biased by a compressive force and unbiased (fully or partially) when the compressive force is removed (fully or partially). In the examples shown in FIGS. 1A-2B, biasing component 122 is a compressive spring and force applicator 120 is a plunger. In these examples, when biasing component 122 becomes unbiased, it decompresses. A sudden removal of the biasing force applied to biasing component 122 would cause biasing component 122 to suddenly decompress. Other examples using a compressive element could implement magnetic, elastomeric materials, hydraulic, or pneumatic biasing components. In one or more embodiments, biasing component 122 can include a tensile element, such as tension springs, elastic bands, hydraulic/pneumatic tensioners, or tension rods.

With reference to the example embodiment shown in in FIGS. 1A-2B, PCB 104 is initially retained within protective housing 102 without any tampering. A physical force can be applied to force applicator 120, embodied as a plunger (e.g., a rod or piston moving within a cylinder 124), that causes the plunger to apply a compressive force to biasing component 122, embodied as a compressive spring. Other embodiments can include compressive springs that do not use coils. The spring can be made of metal or other material that can have a bias, be deformed, and return to its original shape when a biasing force is removed.

When compressive spring is compressed, it stores mechanical energy, including kinetic energy. When tampering causes protective housing 102 or PCB 104 to be moved, such as for removing PCB 104 from housing 102 (fully or partially), a physical force applied to the plunger is removed, causing removal of the compressive force applied by the plunger to the compressive spring. This causes the compressive spring to move to its unbiased position, which causes a sudden release, also referred to as a burst, of the stored kinetic energy.

With reference to FIGS. 1A-1C, a first scenario is shown in which side 105 of protective housing 102 includes an elongated ramp portion 106 that slopes downward and is preceded by a first portion 107 of side 105 that spans from a first corner (shown on the left side of FIGS. 1A-1C) to the beginning (highest point, point 142) of ramp portion 106. A bottom end of ramp portion 106 at point 146 is followed by a steep wall 108 that rises from the bottom of ramp portion 106 at its lowest point to a second portion 109 of side 105. Steep wall 108 can have a steep upward slope or rise vertically. The slope of steep wall 108 is at least twice as steep as the slope of ramp portion 106. Second portion 109 spans from point 148 to a second corner (opposite the first corner and shown on the right side of FIGS. 1A-1C) of housing 102. In the example shown, first portion 107 and second portion 109 are disposed at about the same height (relative to the bottom of ramp portion 106) and are generally flat. In other embodiments, the first portion 107 and second portion 109 can have different heights and shapes.

A critical factor to the configuration of ME component 110 and protective housing 102 is configuring ME component 110 and protective housing 102 so that ME component 110 is caused to be biased and store mechanical energy that will be quickly released as a burst of kinetic energy sufficient to trigger EE component 112. The amount of mechanical energy stored needs to be an appropriate and sufficient amount to be released as a burst of kinetic energy sufficient to trigger EE component 112 to generate an electrical spike of a desired magnitude for interacting with protective circuit 114.

In the embodiment shown in FIGS. 1A-1C, an increasing amount of pressure is applied by protective housing 102 to force applicator 120 as the position of force applicator 120 is caused to be moved towards the bottom of ramp portion 106 (indicated by point 146). The increase of pressure applied to force applicator 120 causes an increase in biasing of biasing component 122, which causes an increase in energy generated and stored by biasing component 122 (and thus by ME component 110). Ramp portion 106 and ME component 122 are thus configured so that when force applicator 120 is positioned at or adjacent to the bottom end of ramp 106, an appropriate amount of mechanical energy has been generated and is stored by ME component 110.

An additional critical factor is configuration of protective housing 102 so that relative positioning of second portion 109 relative to the bottom end of ramp 106 allows for quick release of the kinetic energy stored as mechanical energy. Movement of ME component 110 relative to protective housing 102 causes force applicator 120 to pass the bottom of ramp portion 106 at point 146. Once force applicator 120 passes point 146, the force applied to force applicator 120 by protective housing 102 is quickly removed, allowing biasing component 122 to become unbiased and release its stored mechanical energy. The speed at which biasing component 122 is unbiased and the amount of stored mechanical energy stored and being released governs the magnitude and duration of the electrical spike. The speed at which the force applied to force applicator 120 is removed and the release of biasing component 122 occurs is governed by the height differential between the bottom of ramp, the relative height of second portion 109, the slope or vertical orientation of steep wall 108, and a degree of stiffness of biasing member 122. The amount of mechanical energy stored is governed by factors such as amount of displacement of force applicator 120 and the corresponding amount that biasing component 122 is biased when force applicator 122 is disposed at point 146 immediately prior to release, as well as the degree of stiffness of biasing component 122.

EE component 112, in at least some embodiments, includes components such as a piezoelectric element or a magnet and magnetic coil set that converts mechanical energy into electrical energy. ME component 110 transfers the kinetic energy burst to EE component 112. When EE component 112 includes a magnet and magnetic coil set, sudden decompression of biasing component 122 generates a force (caused by the kinetic energy burst) that can make the magnet travel through the magnetic coil. When EE component 112 includes a piezoelectric element, sudden decompression of biasing component 122 generates a force (caused by the kinetic energy burst) that can make the piezo to bend. Both mechanisms (meaning the movement of the magnet through the magnetic coil or the bending of the piezo) can generate energy.

EE component 112 is configured to release an electrical energy spike responsive to the kinetic energy burst. The electrical energy spike is transferred to protection circuit 114 to cause the first action set and optionally the second action set. In certain embodiments, thee energy spike can be transferred from EE component 112 only to protection circuit 114. In certain embodiments the electrical energy spike can be transferred directly to one or more of protected element(s) and/or to protection circuit 114.

In one or more embodiments, protected elements 116 can include, for example, one or more storage devices (not depicted in the figures, but well understood) that store sensitive information or specific data or addresses of data stored by the storage device(s). Protection circuit 114 can cause the disabling (full or partial; permanent or temporary) of or erasure of data from the storage device(s). In one or more embodiments, protected elements 116 can include one or more addressable stored data items. In one or more embodiments, protected elements 116 can include a flag, which can be an addressable data location in the storage device(s). In one or more embodiments, protected elements 116 can include a hardware component, a firmware component, or a software component of circuits include in PCB 104. Protection circuit 116 can cause (full or partial; permanent or temporary) disabling of the component.

Protection circuit 114 can perform the first and/or second action sets described above. The first action set can be triggered by the spike of energy output by EE component 112 and the second action set can be triggered at a future time by a triggering event. When performing the first action set, protection circuit 114 can perform all or a portion of the disabling of or erasure of the data from the storage device(s) responsive to the spike of energy and/or setting a flag. When performing the second action set, protection circuit 114 can perform all or a portion of the disabling of or erasure of the data from the storage device(s) as the second action set contingent upon the flag being set (e.g., by the first action set) and/or contingent upon a triggering event, as described above.

Protection circuit 114 can include, for example, a microcontroller unit (MCU) and a volatile memory. Protection circuit 114, in certain embodiments, provides protection at a logical (meaning data) level. Thus, in such embodiments, a physical relationship is not needed between protection circuit 114 and protected elements 116 other than the ability to communicate data (e.g., via wired or wireless communication).

In certain embodiments, protection circuit 114 can be integrated with one or more of protected elements 116.

FIG. 1A shows a stage once movement of PCB 104 from protective housing 102 (indicated by arrow 130) has been initiated. In one or more embodiments, ME component 110 may have been installed with force applicator 120 at point 142 at the top of the ramp, with movement 130 having progressed until force applicator 120 arrives at point 144. In this embodiment, mechanical energy was generated and stored by ME component 110 as its biasing component 122 became increasingly biased (e.g., compressed). In one or more embodiments, ME component 110 may have been installed with force applicator positioned at point 144. In either case, at this point, protective housing 102 applies a force to force applicator 120, causing force applicator 120 to apply a compression force to biasing component 122 and biasing (e.g., compression) of biasing component 122, and thus storing mechanical energy in biasing component 122. The amount of compression will govern the amount of mechanical energy stored and the amount of kinetic energy that can be released.

FIG. 1B shows a next stage once PCB 104 has been moved such that force applicator 120 has been moved to point 146, which is the bottom of ramp portion 106. As force applicator 120 is moved from point 144 to point 146, the amount of mechanical energy generated and stored by ME component 110 increases. When located at point 146, force applicator 120 is at its lowest point. The force applied by protective housing 102 to force applicator 120 has increased to the maximum force available for this configuration, which causes force applicator 120 to apply a maximum available compression force to biasing component 122. This causes a maximum compression available of biasing component 122 for this configuration, and therefore has caused generation and storage of a maximum amount of energy (for this configuration) by biasing component 122.

FIG. 1C shows a next stage once PCB 104 has been moved so that force applicator 120 has been moved past point 146 to point 148 on the second portion 109. The movement in the direction of arrow 130 from point 146 to 148 can occur quickly due to the short distance (or no distance) between points 146 and 148 and the high slope or vertical orientation of steep wall 108. At this stage, force is no longer applied by protective housing 102 to force applicator 120, and force applicator 120 no longer applies any compression force to biasing component 122. Biasing component 122 is suddenly unbiased and suddenly releases its stored mechanical energy as kinetic energy. The kinetic energy is released by ME component 110 for transfer to EE component 112, which released a sudden electrical spike to protection circuit 114.

Accordingly, factors such as the shape of ramp portion 206 (including steep wall 108), positioning of force applicator 120 relative to ramp potion 106, second portion 109, and biasing component 122, and stiffness of the biasing component can be designed to obtain a desired magnitude and duration of the electrical spike.

With reference to FIGS. 2A and 2B, another example of tamper detection system 100 is shown in which protective housing 102 is provided with a rectangular notch 202 disposed between first and second portions of side 105. As shown in FIG. 2A, upon installation, ME component 110 is disposed below notch 202 and in contact with a bottom surface 204 of notch 202, with protective housing 102 applying a maximum force (for this configuration) to force applicator 120. At installation, force applicator 120 can apply a maximum available compression force to biasing component 122, which can cause a maximum compression available of biasing component 122 for this configuration and can therefore cause storage of a maximum amount of mechanical energy (for this configuration) by biasing component 122. The amount of energy stored is a factor of the amount of displacement of force applicator 120, the corresponding amount that biasing component 122 is biased, and the degree of stiffness of biasing component 122. Following installation, as indicated by arrow 130, movement of PCB 104 from protective housing 102 has been initiated, with ME component remaining below notch 202.

FIG. 2B shows a next stage once PCB 104 has been moved such that force applicator 120 has been moved past point 246 and to point 248 which is located on the second portion of side 105. The movement past notch 202 from point 246 to 248 can occur suddenly due to the short distance (or no distance) between points 246 and 248 and the high slope or vertical orientation of the far wall of notch 202, referred to as steep wall 208, that was traversed. Once force applicator 120 has been moved from point 246 to point 248, force is no longer applied by protective housing 102 to force applicator 120, and force applicator 120 no longer applies compression force to biasing component 122. Biasing component 122 is suddenly unbiased and suddenly releases its stored mechanical energy as kinetic energy. The kinetic energy is released by ME component 110 for transfer to EE component 112, which releases a sudden electrical spike to protection circuit 114.

As in the embodiment shown in FIGS. 1A-1C, the speed at which biasing component 122 is unbiased as well as the amount of mechanical energy stored and released governs the magnitude and duration of the electrical spike. The speed at which the force applied to force applicator 120 is removed is governed by the height differential between the bottom of notch 202 and the relative height of the top of notch 202 and any slope of steep wall 208. The speed at which biasing component 122 is released is governed by speed of removal of biasing force by force applicator 120 on biasing component 122 and the degree of stiffness of biasing component. Accordingly, factors such as the shape of notch 202 (including steep wall 208), positioning of force applicator 120 relative to notch 202 and biasing component 122, and stiffness of the biasing component can be designed to obtain a desired magnitude and duration of the electrical spike.

The shapes of protective housing 102 shown in FIGS. 1A-2B are provided as examples and are not meant to limit the shape of protective housing to the particular shapes shown. For example, the shape of protective housing 102 can be configured to cause a release (and optionally, also storage) of tensile energy when PCB 104 is moved relative to protective housing 102.

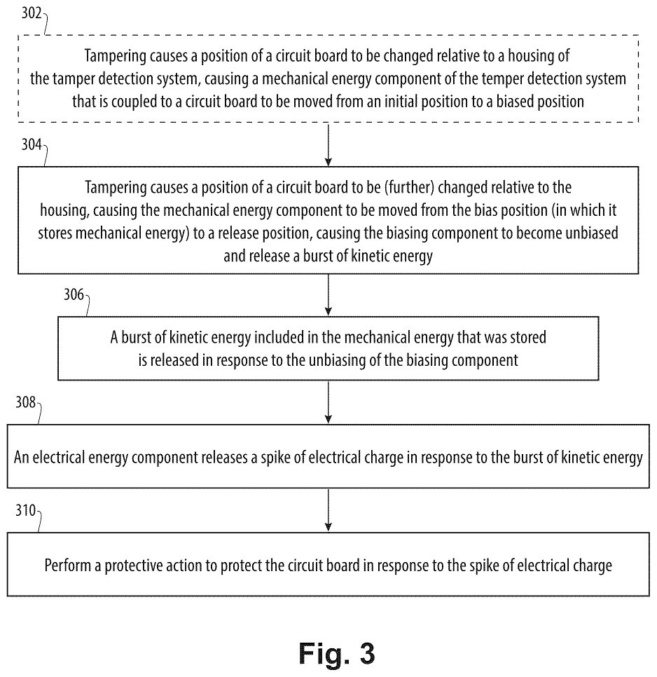

With reference now to FIG. 3, shown is/are a flowchart demonstrating implementation of the various exemplary embodiments. The method illustrated by the flowchart in FIG. 3 is performed by a tamper detection system, such as tamper detection system 100 shown in FIGS. 1A-2B. It is noted that the order of operations shown in FIG. 3 is not limiting and that, depending on implementation, it is possible that certain operations may be skipped, different operations may be added or substituted, some operations may be performed in parallel instead of strictly sequentially, or selected operations or groups of operations may be performed in a separate application following the embodiments described herein. In addition, some operations of FIG. 3, though depicted as sequential may, in a given implementation, appear to take place substantially simultaneously, depending on how fast the bursts of energy and/or corresponding electrical charge spikes take place.

With reference to FIG. 3, an example method 300 is shown for detecting unauthorized access to a circuit board (such as PCB 104 shown in FIGS. 1A-2B). The method begins at block 302. In one or more embodiments, at optional block 302, a mechanical energy component of the tamper detection system (such as ME component 110 shown in FIGS. 1A-2B) is moved from an initial position to a biased position due to tampering that causes a position of the circuit board to be changed relative to a housing of the tamper detection system, such as protective housing 102 shown in FIGS. 1A-2B. The mechanical energy component is coupled to the circuit board. When in the initial position, a biasing component (such as biasing component 122 shown in FIGS. 1A-2B) of the mechanical energy component is caused (e.g., by the housing due to a shape of the housing) to be less biased than when in the bias position. Moving from the initial position (e.g., in which a force applicator (such as force applicator 120 shown in FIGS. 1A-1C) applying a force to the biasing component) is disposed at point 142 shown in FIGS. 1A-1C) to the bias position (e.g., in which the force applicator is disposed at point 144 shown in FIGS. 1A-1C) causes the biasing component to generate and store mechanical energy.

At block 304, the mechanical energy component is moved from the bias position (in which it stores mechanical energy) to a release position due to tampering (or a continuation of the tampering) causing a position of the circuit board to be (further) changed relative to the housing.

At block 306, a burst of kinetic energy included in the mechanical energy that was stored is released in response to the unbiasing of the biasing component.

When the mechanical energy component is disposed in the bias position, the housing, due to a shape of the housing, causes the biasing component to be biased. In the bias position, the housing, due to its shape, causes application of a first force to the biasing component. In a first nonlimiting example, a ramp of the housing (e.g., elongated ramp portion 106 shown in FIGS. 1A-1C, at points such as point 144 between point 142 and 146) applies force to an applicator, and the applicator applies the first force to the biasing component. In a second nonlimiting example, the housing includes a notch (e.g., notch 202 shown in FIGS. 2A and 2B) having a different first and second levels that apply different amounts of force to the applicator, causing the applicator to apply different amounts of force to the biasing component. In the bias position, the first level of the notch causes the housing to apply a force to the applicator and the applicator applies the first force to the biasing component.

When the mechanical energy component is disposed in the release position, the housing, due to its shape, causes the biasing component to be unbiased. In the release position, the housing, due to its shape, causes application of no force or a second force that is less than the first force to the biasing component. In the first nonlimiting example, movement of the PCB 104 relative to the housing 102 causes the applicator to move past point the ramp to point 148 (in a direction away from point 146) and past steep wall 108, causing the housing to apply no force or a small force to the applicator, causing the applicator to apply no force or the second force to the biasing component. In the second nonlimiting example, movement of the PCB 104 relative to the housing 102 causes the applicator to move past the first level of the notch to or past point 248 (in a direction away from a portion of the notch having the first level) and past steep wall 208, causing the housing 102 (e.g., at inner surface 103 as shown in FIGS. 2A and 2B) to apply no force or a small force to the applicator, causing the applicator to apply no force or the second force to the biasing component.

In an embodiment, causation of the application by the housing 102 of the first force to the biasing component can be in response to an initial change in the position of the circuit board 104 relative to the housing 102, wherein the initial change precedes the change in position of the circuit board 104 relative to the housing 102 that caused the unbiasing of the biasing component. This embodiment can be illustrated using the nonlimiting example shown in FIG. 1A. Initially, the applicator can be in contact with the lower surface of the housing 102 at point 142, in which the housing 102 applies little or no force to the applicator. An initial change in the position of the circuit board 104 relative to the housing 102 can cause the applicator to move from point 142 towards point 146, e.g., to point 144. Thus, the initial change in position of the circuit board 104 relative to the housing 102 causes an increase in the force applied by the housing 102 to the applicator and by the applicator to the biasing component. Further, this initial change causes storage of mechanical energy by the biasing component. The amount of mechanical energy stored by biasing component increases until the applicator reaches point 146.

For example, in one or more embodiments, the shape of the housing 102 includes a step having a first level and a second level different than the first level. When the mechanical energy component is disposed in the bias position relative to the housing 102, the first level of the step causes the housing 102 to apply a first force to a force applicator of the mechanical energy component, and the force applicator applies a biasing force to the biasing component, which causes the biasing to be biased. When the mechanical energy component is disposed in the release position relative to the housing 102, the second level of the step causes the housing 102 to apply less of the force to the force applicator, and the force applicator applies less or no biasing force to the biasing component, which causes the biasing to be unbiased.

At block 308, an electrical energy component (such as EE component 112 shown in FIGS. 1A-2B) releases a spike of electrical charge in response to the burst of kinetic energy.

In one or more embodiments, the energy component includes a piezoelectric member formed of a piezoelectric material, and the kinetic energy causes mechanical deformation of the piezoelectric material, which causes the piezoelectric material to release the spike of electrical charge.

In one or more embodiments, the electrical energy component includes a magnet and a coil formed of wire having one or more turns, wherein the kinetic energy causes relative movement between the magnet and the coil to induce a current, wherein the induced current causes release of the spike of electrical charge.

At block 310, a protective action is caused to be performed to protect a protected element (such as of protected elements 116 shown in FIGS. 1A-2B) in response to the spike of electrical charge.

In one or more embodiments, the protective action includes causing erasure of stored security-related information, disabling one or more functions provided by one or more circuits included in or coupled to the circuit board, outputting an alarm indication, record a security breach event, and/or reporting the security breach event.

In one or more embodiments, the protection action is performed immediately after the spike of electrical charge is released or following a delay after the spike of electrical charge is released.

In one or more embodiments, the protective action is performed in response to powerup or an action of a device that includes or is coupled to the circuit board and/or to the protective element.

Potential advantages of the disclosed tamper detection system and method include, but are not limited to, the ability to detect tampering with a circuit board of a device when it is physically removed from a housing (by moving either the circuit board or the housing) and cause performance of one or more protective actions. The monitoring for the tampering and the protective actions can be performed when the device is remote and/or difficult to access for monitoring and/or maintaining. The tamper detection system stores and releases mechanical energy to provide an electrical spike that will trigger the protective actions. The mechanical energy can be stored at installation by configuring a biasing component of the tamper detection system to be already biased, or the mechanical energy can be generated and stored (as well as released) by the relative movement of the circuit board and housing. The tamper detection system does not need to use an electrical power supply, such as from a battery or external power source, to monitor for tampering or to cause the protective action(s), which precludes the need to replace batteries, avoids shipping restrictions, and lasts for the lifetime of the device. A first set of protection actions can be triggered by the electrical spike and can further cause a second set of protection actions to be performed at a future time in response to a future event or condition.

The above-described tamper detection system is adaptable to any type of circuit contained within a housing, where access to the circuit is unexpected or unwanted, including arrangements that include circuits formed on flexible substrates, three-dimensional (3D) circuits formed on objects, and the like. Further, the above-described systems, methods, and devices are usable with any type of circuit that can be configured to cooperate with the discussed electrical and mechanical energy components and arrangements discussed herein, to provide erasure of information and/or a record or log of the unauthorized or unexpected access, as will be understood.

It is to be understood that the above description is intended to be illustrative, and not restrictive. Many other implementation examples are apparent upon reading and understanding the above description. Although the disclosure describes specific examples, it is recognized that the systems and methods of the disclosure are not limited to the examples described herein, but may be practiced with modifications within the scope of the appended claims. Accordingly, the specification and drawings are to be regarded in an illustrative sense rather than a restrictive sense. The scope of the disclosure should, therefore, be determined with reference to the appended claims, along with the full scope of equivalents to which such claims are entitled.

It is understood that embodiments of the disclosure herein may be configured as a system, method, or combination thereof.

It is to be appreciated that the concepts, systems, circuits, and techniques sought to be protected herein are not limited to use in the example applications described herein (e.g., industrial applications), but rather may be useful in substantially any application where it is desired to detect tampering or intrusion, especially in a remotely located device or system or in a device or system which is challenging to access, as well as any application where it is desired to receive decision support for each step in an automated fashion.

Having described various embodiments, which serve to illustrate various concepts, structures and techniques that are the subject of this patent, it will now become apparent to those of ordinary skill in the art that other embodiments incorporating these concepts, structures and techniques may be used. Additionally, elements of different embodiments described herein may be combined to form other embodiments not specifically set forth above.

We claim:

1. A tamper detection system for detection of unauthorized access to a circuit board, the tamper detection system comprising:
a housing within which the circuit board is disposed;
a mechanical energy component coupled to the circuit board and configured to move between a biased position to a release position when tampering causes a position of the circuit board to be changed relative to the housing, wherein when in the biased position, a biasing component of the mechanical energy component is biased and stores mechanical energy, and in response to moving to the release position, the biasing component becomes unbiased and releases a burst of kinetic energy;
an electrical energy component configured to release a spike of electrical charge in response to the burst of kinetic energy; and
a protection circuit configured to respond to the spike of electrical charge by causing performance of a protective action to a protected element.

2. The tamper detection system of claim 1, wherein when the mechanical energy component is disposed in the biased position, the housing, due to its shape, causes the biasing component to be biased, and when the mechanical energy component is disposed in the release position, the housing, due to its shape, causes the biasing component to be unbiased.

3. The tamper detection system of claim 1, wherein the mechanical energy component is further configured to move from an initial position to the bias position when tampering causes the position of the circuit board to be changed relative to the housing, wherein when in the initial position, the biasing component is caused by the housing, due to its shape, to be less biased than when in the bias position, and moving from the initial position to the bias position causes the biasing component to generate and store at least a portion of the mechanical energy.

4. The tamper detection system of claim 1, wherein the energy component includes a piezoelectric member formed of a piezoelectric material, and the kinetic energy causes mechanical deformation of the piezoelectric material, which causes the piezoelectric material to release the spike of electrical charge.

5. The tamper detection system of claim 1, wherein the energy component includes a magnet and a coil formed of wire having one or more turns, wherein the kinetic energy causes relative movement between the magnet and the coil to induce a current, wherein the induced current causes release of the spike of electrical charge.

6. The tamper detection system of claim 1, wherein the protective action includes causing at least one of the group including: erasure of stored security-related information, disabling one or more functions provided by one or more circuits, outputting an alarm indication, recording a security breach event, and reporting the security breach event.

7. The tamper detection system of claim 1, wherein the protection action is performed immediately after the spike of electrical charge is released or following a delay after the spike of electrical charge is released.

8. The tamper detection system of claim 1, wherein the protective action is performed in response to at least one of the group including a powerup and, an action of a device that includes or is coupled to at least one of the group including the circuit and the protected element.

9. The tamper detection system of claim 1, wherein the industrial device operates in an operational technology portion of an industrial system.

10. The tamper detection system of claim 2, wherein the shape of the housing includes a notch having a first level and a second level different than the first level, wherein:
when the mechanical energy component is disposed in the bias position relative to the housing, the first level of the notch causes the housing to apply a first force to a force applicator of the mechanical energy component, and the force applicator applies a biasing force to the biasing component, which causes the biasing to be biased, and
when the mechanical energy component is disposed in the release position relative to the housing, the second level of the notch causes the housing to apply less of the force to the force applicator, and the force applicator applies less or no biasing force to the biasing component, which causes the biasing to be unbiased.

11. A method of detecting unauthorized access to a circuit board, the method comprising:
causing, in response to a position of the circuit board being changed relative to a housing within which the circuit board is disposed, unbiasing of a biasing component;
releasing, in response to the unbiasing of the biasing component, a burst of kinetic energy included in mechanical energy stored by the biasing component;
releasing, in response to the burst of kinetic energy, a spike of electrical charge; and
causing, in response to the spike of electrical charge, performance of a protective action to a protected element.

12. The method of claim 11, wherein releasing the spike of charge is caused by mechanical deformation of a piezoelectric material of a piezoelectric member, the mechanical deformation being in response to the release of the kinetic energy.

13. The method of claim 11, wherein releasing the spike of charge is caused by induction of a current caused by relative movement between a magnet and a coil formed of wire having one or more turns, the relative movement being in response to the release of the kinetic energy.

14. The method of claim 11, wherein the protective action includes causing at least one of the group including: erasure of stored security-related information, disabling one or more functions provided by one or more circuits included in or coupled to the circuit board, outputting an alarm indication, recording a security breach event, and reporting the security breach event.

15. The method of claim 11, wherein the protection action is performed immediately after the spike of electrical charge is released or following a delay after the spike of electrical charge is released.

16. The method of claim 11, wherein the protective action is performed in response to at least one of the group including a powerup and an action of a device that includes or is coupled to at least one of the group including the circuit board and the protected element.

17. The method of claim 11, further comprising causing the biasing component to be biased and store at least a portion of the mechanical energy in response to the housing, due to a shape of the housing, causing application by the housing of a first force to the biasing component, wherein when the position of the circuit board is changed relative to the housing, the housing causes application of no force or a second force that is less than the first force to the biasing component.

18. The method of claim 17, wherein causing the application by the housing of the first force to the biasing component is in response to an initial change in the position of the circuit board relative to the housing that precedes the position of the circuit board being changed relative to the housing.

19. An industrial device comprising:
a circuit board;
a housing within which the circuit board is disposed;
a mechanical energy component coupled to the circuit board and configured to move between a biased position to a release position when tampering causes a position of the circuit board to be changed relative to the housing, wherein when in the biased position, a biasing component of the mechanical energy component is biased and stores mechanical energy, and in response to moving to the release position, the biasing component becomes unbiased and releases a burst of kinetic energy;
an electrical energy component coupled to the mechanical energy component and configured to release a spike of electrical charge in response to the burst of kinetic energy;
a protection circuit in operable communication with the circuit board and configured to respond to the spike of electrical charge by causing performance of a protective action to protect a protected element that is in operable communication with the protection circuit.

20. The industrial device of claim 19, wherein when the mechanical energy component is disposed in the biased position, the housing, due to a shape of the housing, causes the biasing component to be biased, and when the mechanical energy component is disposed in the release position, the housing, due to the shape of the housing, causes the biasing component to be unbiased.
